(19) United States
(12) Patent Application Publication
(10) Pub. No.: US 2025/0107059 A1
(43) Pub. Date: Mar. 27, 2025

(54) GATE METAL JUMPER IN STACKED FET SRAM

(71) Applicant: International Business Machines Corporation, Armonk, NY (US)

(72) Inventors: Chen Zhang, Santa Clara, CA (US); Ruilong Xie, Niskayuna, NY (US); LEI ZHUANG, Ridgefield, CT (US); Junli Wang, Slingerlands, NY (US)

(21) Appl. No.: 18/474,574

(22) Filed: Sep. 26, 2023

(51) Int. Cl. H10B 10/00; G11C 11/412; H01L 21/8234; H01L 27/088; H01L 29/06; H01L 29/423; H01L 29/66; H01L 29/775; H01L 29/786

(52) U.S. Cl. CPC H10B 10/12; G11C 11/412; H10D 30/014; H10D 30/43; H10D 30/6735; H10D 30/6757; H10D 62/121; H10D 64/017; H10D 84/0128; H10D 84/038; H10D 84/83

(57) ABSTRACT

A semiconductor structure may include a first pass gate oriented along a first line. A semiconductor structure may include a first inverter in line with the first line. The first inverter may include a first channel region, a second channel region stacked above the first channel region. The semiconductor structure may also include an inverter gate around the first channel region and the second channel region, with a gate extension above the pass gate.

### BACKGROUND

The present invention relates generally to the field of static random-access memory (SRAM), and more particularly to a gate metal jumper laterally extended over a pass gate channel.

SRAM is a component of digital integrated circuits used to store temporary data within SRAM cells. Each SRAM cell includes an inverter, a fundamental digital logic gate. The primary function of the inverter is to invert the input signal, producing an output that is the logical complement of the input. In SRAM cells, pairs of inverters are interconnected in a cross-coupled arrangement. This cross-couple forms a latch-like structure that maintains integrity of the stored data.

In an SRAM cell, the cross-coupled inverters are employed to create bistable states, representing binary values (0 or 1). The voltage levels at the nodes connecting the inverters determine whether the state is 0 or 1, and this state is preserved through positive feedback. During read and write operations, the state is manipulated by applying appropriate voltages to the bitlines, enabling data storage and retrieval. However, SRAM cells are volatile, necessitating periodic refresh cycles to retain data. The unique design of cross-coupled inverters within SRAM cells facilitates rapid access times and efficient data storage.

### SUMMARY

In some aspects, the techniques described herein relate to a semiconductor structure, including: a first pass gate oriented along a first line; a first inverter in line with the first line, including: a first channel region; a second channel region stacked above the first channel region; and an inverter gate around the first channel region and the second channel region, including a gate extension above the pass gate.

In some aspects, the techniques described herein relate to a method, including: forming a separating insulator oriented along a first line between channel regions for a first pass gate and a first inverter; etching a gate extension gap into the separating insulator above the pass gate; and forming an inverter gate, wherein the inverter gate fills the gate extension gap with a high-K metal gate material to form a gate extension.

In some aspects, the techniques described herein relate to a semiconductor structure, including: an inverter gate configured to activate an inverter gate transistor; a pass gate; and a separating insulator between the inverter gate and the pass gate, wherein the inverter gate includes a gate extension extending horizontally along a first line in a location vertically above the pass gate and the separating insulator.

### BRIEF DESCRIPTION OF THE DRAWINGS

FIG. 1 depicts a schematic top see-through view of a semiconductor structure, in accordance with one embodiment of the present invention.

FIG. 2 depicts a cross-sectional side view of the semiconductor structure of FIG. 1 along line A-A′ at one stage of fabrication, in accordance with one embodiment of the present invention.

FIG. 3 depicts a cross-sectional side view of the semiconductor structure of FIG. 1 along line A-A′ at one stage of fabrication, in accordance with one embodiment of the present invention.

FIG. 4 depicts a cross-sectional side view of the semiconductor structure of FIG. 1 along line A-A′ at one stage of fabrication, in accordance with one embodiment of the present invention.

FIG. 5 depicts a cross-sectional side view of the semiconductor structure of FIG. 1 along line A-A′ at one stage of fabrication, in accordance with one embodiment of the present invention.

FIG. 6 depicts a cross-sectional side view of the semiconductor structure of FIG. 1 along line A-A′ at one stage of fabrication, in accordance with one embodiment of the present invention.

FIG. 7 depicts a cross-sectional side view of the semiconductor structure of FIG. 1 along line A-A′ at one stage of fabrication, in accordance with one embodiment of the present invention.

FIG. 8 depicts a cross-sectional side view of the semiconductor structure of FIG. 1 along line A-A′ at one stage of fabrication, in accordance with one embodiment of the present invention.

FIG. 9A depicts a cross-sectional side view of the semiconductor structure of FIG. 1 along line A-A′ at one stage of fabrication, in accordance with one embodiment of the present invention.

FIG. 9B depicts a cross-sectional side view of the semiconductor structure of FIG. 1 along line B-B′ at one stage of fabrication, in accordance with one embodiment of the present invention.

### DETAILED DESCRIPTION

In the following detailed description, reference is made to the accompanying drawings, which show specific examples of embodiments of the invention. These embodiments are described in sufficient detail to enable those skilled in the art to practice them, and it is to be understood that other embodiments may be utilized, and that structural, logical, and electrical changes may be made without departing from the described embodiments. The following detailed description is, therefore, not to be taken in a limiting sense, and the included embodiments are defined by the appended claims.

In the following description, numerous specific details are set forth, such as particular structures, components, materials, dimensions, processing steps and techniques, in order to provide an understanding of the various embodiments of the present application. However, it will be appreciated by one of ordinary skill in the art that the various embodiments of the present application may be practiced without these specific details. In other instances, well-known structures or processing steps have not been described in detail in order to avoid obscuring the present application.

References in the specification to “one embodiment,” “an embodiment,” “certain embodiments,” etc., indicate that the embodiment described may include a particular feature, structure, or characteristic. Moreover, such phrases are not necessarily referring to the same embodiment. Further, when a particular feature, structure, or characteristic is described in connection with an embodiment, it is submitted that it is within the knowledge of one skilled in the art to affect such feature, structure, or characteristic in connection with other embodiments whether or not explicitly described.

For purposes of the description hereinafter, the terms “upper,” “right,” “left,” “vertical,” “horizontal,” “top,” “bottom,” and derivatives thereof shall relate to the disclosed structures and methods, as oriented in the drawing Figures. The terms “above,” “below,” “positioned on,” or “positioned atop” mean that a first element, such as a first structure, is present on a second element, such as a second structure, wherein intervening elements, such as an interface structure may be present between the first element and the second element. The term “direct contact” means that a first element, such as a first structure, and a second element, such as a second structure, are connected without any intermediary conducting, insulating or semiconductor layers at the interface of the two elements.

It will be understood that when an element as a layer, region or substrate is referred to as being “on” or “over” another element, it can be directly on the other element or intervening elements may also be present. In contrast, when an element is referred to as being “directly adjacent,” “directly on,” or “directly over” another element, there are no intervening elements present. It will also be understood that when an element is referred to as being “beneath” or “under” another element, it can be directly below or under the other element, or intervening elements may be present. Additionally, when an element is referred to as being “directly below” or “directly above” another element, intervening elements may be present, but the elements overlap at least partially relative to a vertical axis perpendicular to a major surface. With regard to the fabrication of transistors and integrated circuits, major surface refers to that surface of the semiconductor layer in and about which a plurality of transistors are fabricated, e.g., in a planar process. As used herein, the term “vertical” means substantially orthogonal with respect to the major surface and “horizontal” means substantially parallel to the major surface. Typically, the major surface is along a plane of a monocrystalline silicon layer on which transistor devices are fabricated. Each reference number may refer to an item individually or collectively as a group. For example, a contact 202 may refer to a single contact 202 or multiple contacts 202.

Although the terms first, second, etc. may be used herein to describe various elements, these elements should not be limited by these terms. These terms are only used to distinguish one element from another. For example, a first element could be termed a second element, and, similarly, a second element could be termed a first element, without departing from the scope of example embodiments. As used herein, the term “and/or” includes any and all combinations of one or more of the associated listed items.

The terms “epitaxial growth and/or deposition” and “epitaxially formed and/or grown” mean the growth of a semiconductor material (crystalline material) on a deposition surface of another semiconductor material (crystalline material), in which the semiconductor material being grown (crystalline overlayer) has substantially the same crystalline characteristics as the semiconductor material of the deposition surface (seed material). In an epitaxial deposition process, the chemical reactants provided by the source gases can be controlled and the system parameters can be set so that the depositing atoms arrive at the deposition surface of the semiconductor substrate with sufficient energy to move about on the surface such that the depositing atoms orient themselves to the crystal arrangement of the atoms of the deposition surface. An epitaxially grown semiconductor material can have substantially the same crystalline characteristics as the deposition surface on which the epitaxially grown material is formed. In some embodiments, epitaxial growth and/or deposition processes can be selective to forming on semiconductor surfaces, and may or may not deposit material on other exposed surfaces, such as silicon dioxide or silicon nitride surfaces.

Example embodiments are described herein with reference to cross-sectional illustrations that are schematic illustrations of idealized or simplified embodiments (and intermediate structures). As such, variations from the shapes of the illustrations as a result, for example, of manufacturing techniques and/or tolerances, may be expected. Thus, the regions illustrated in the figures are schematic in nature and their shapes do not necessarily illustrate the actual shape of a region of a device and do not limit the scope.

It is to be understood that other embodiments may be used, and structural or logical changes may be made, without departing from the spirit and scope defined by the claims. The description of the embodiments is not limiting. In particular, elements of the embodiments described hereinafter may be combined with elements of different embodiments.

In some embodiments, etching mask layer(s) may be provided, and the layers that are not protected thereby are removed. For example, as is understood in the art, a mask layer, sometimes referred to as a photomask, may be provided by forming a layer of photoresist material on another layer, exposing the photoresist material to a pattern of light, and developing the exposed photoresist material. An etching process, such as a reactive ion etch (RIE), may be used to form patterns (e.g., openings) by removing portions of another layer. After etching, the mask layer may be removed using a conventional plasma ashing or stripping process.

Accordingly, the pattern of the mask layer facilitates the removal of another layer, such as an amorphous SiO2 layer and/or a conductive oxide diffusion barrier, for example, in areas where the mask layer has not been deposited.

For the sake of brevity, conventional techniques related to semiconductor structure and integrated circuit (IC) fabrication may or may not be described in detail herein. Moreover, the various tasks and process steps described herein can be incorporated into a more comprehensive procedure or process having additional steps or functionality not described in detail herein. In particular, various steps in the manufacture of semiconductor structures and semiconductor-based ICs are well known and so, in the interest of brevity, many conventional steps will only be mentioned briefly herein or will be omitted entirely without providing the well-known process details.

Patterning a cross-coupled structure in an SRAM cell is a formidable task due to its intricacy and the demands of modern semiconductor manufacturing. These cross-coupled inverters are typically extremely small and tightly integrated, often pushing the boundaries of fabrication technology. These problems can become more problematic in a stacked field-effect transistor (FET) that relies of matching halves of pull-up, pull-down, and pass-gate transistors. The SRAM also needs electrical connection between these halves without shorting to any of the contacts that are also present in the SRAM cell. Achieving precise size and alignment required for is challenging, and even slight deviations during the patterning process can result in defective cells or performance issues. As semiconductor technology continues to shrink, the challenges intensify. Smaller feature sizes demand advanced lithography techniques and materials, adding complexity and cost to the manufacturing process. Overall, the intricacies and precision required to pattern cross-coupled inverters in SRAM cells make it a critical and challenging aspect of semiconductor fabrication, especially as technology advances to smaller nodes.

The embodiments discussed herein, therefore, include a self-aligning extension of an inverter gate to connect to a cross-couple of an SRAM cell. That is, rather than patterning a jumper or a cross-couple directly between a gate of a first inverter and a source/drain (S/D) in a matching “half” of the SRAM on an adjacent line, the inverter gate itself includes an extension that is self-aligned above the pass gate (i.e., on the same half as the inverter). This self-aligning insulates the extension apart from a bitline contact regardless of the lithographic precision or etching accuracy of the processes used to metalize the extension.

In some aspects, the techniques described herein relate to a semiconductor structure, including: a first pass gate oriented along a first line; a first inverter in line with the first line, including: a first channel region; a second channel region stacked above the first channel region. The inverter having a first channel region and a second channel region stacked above the first channel region enables compact fabrication which improves the overall size requirements (smaller is better) and efficiency of the semiconductor structure. To efficiently activate the first channel region and the second channel region, a semiconductor structure may include an inverter gate around the first channel region and the second channel region, including a gate extension above the pass gate. The gate extension provides the technical benefit of extending the electrical connectivity of the inverter gate. This gate extension may be used, for example, to provide an electrical connection to a cross couple coupling the gate extension to a second inverter. That is, the cross couple may be electrically connected between the gate extension and a source/drain (S/D) of the second inverter. This electrical connection enables the inverters to be used as part of a static random access memory (SRAM) device. In some aspects, the techniques described herein relate to a semiconductor structure with the second inverter not oriented along the first line to further increase density and efficiency of the semiconductor structure.

In some aspects, the techniques described herein relate to a semiconductor structure, wherein the first channel region includes nanosheet layers. The nanosheet layers provide the technical benefit of small and precise fabrication, which increases density and reduces defects for channel regions within semiconductor structures generally. In some aspects, the techniques described herein relate to a semiconductor structure, wherein the inverter gate is confined laterally by a gate spacer. The gate spacer provides the technical benefit of self-aligning the inverter gate during fabrication. In some aspects, the techniques described herein relate to a semiconductor structure, further including a separating insulator separating the inverter gate from the pass gate. The separating insulator provides the technical benefit of insulation between the gates, and in certain embodiments may be fabricated within the gate spacer to maintain the self-aligning nature of the inverter gate and pass gate along the first line.

In some aspects, the techniques described herein relate to a semiconductor structure, wherein the separating insulator includes a first vertical section, a first horizontal section, and a second vertical section. The multiple sections of the separating insulator provide the benefit of insulating the inverter gate from the pass gate, while leaving room for the gate extension above the pass gate.

In some aspects, the techniques described herein relate to a method, including: forming a separating insulator oriented along a first line between channel regions for a first pass gate and a first inverter; etching a gate extension gap into the separating insulator above the pass gate; and forming an inverter gate, wherein the inverter gate fills the gate extension gap with a high-K metal gate material to form a gate extension. The gate extension provides the technical benefit of extending the electrical connectivity of the inverter gate. This gate extension may be used, for example, to provide an electrical connection to a cross couple coupling the gate extension to a second inverter.

In some aspects, the techniques described herein relate to a method, further including forming a vertical etch gap in a sacrificial dielectric between the channel regions for the first pass gate and the first inverter. In some aspects, the techniques described herein relate to a method, further including forming a horizontal etch gap above the first pass gate, wherein etching the horizontal etch gap includes etching a nanosheet. The nanosheet layers provide the technical benefit of small and precise fabrication, which increases density and reduces defects for channel regions within semiconductor structures generally. In some aspects, the techniques described herein relate to a method, further including forming a cross-couple between the gate extension and source/drain of a second inverter.

In some aspects, the techniques described herein relate to a method, wherein the second inverter is not oriented along the first line to further increase density and efficiency of the semiconductor structure. In some aspects, the techniques described herein relate to a method, wherein the gate extension gap is self-aligned between a gate spacer, which provides the technical benefit of fabricating an electrical connection structure that does not rely on lithographic patterning extending over the pass gate. Lithographic patterning can be a source of defects, so a self-aligned gate extension eliminates the defects for this particular stage of fabrication.

In some aspects, the techniques described herein relate to a semiconductor structure, including: an inverter gate configured to activate an inverter gate transistor; a pass gate; and a separating insulator between the inverter gate and the pass gate, wherein the inverter gate includes a gate extension extending horizontally along a first line in a location vertically above the pass gate and the separating insulator. The gate extension provides the technical benefit of extending the electrical connectivity of the inverter gate. This gate extension may be used, for example, to provide an electrical connection to a cross couple coupling the gate extension to a second inverter. That is, the cross couple may be electrically connected between the gate extension and a source/drain (S/D) of the second inverter. This electrical connection enables the inverters to be used as part of a static random access memory (SRAM) device. In some aspects, the techniques described herein relate to a semiconductor structure with the second inverter not oriented along the first line to further increase density and efficiency of the semiconductor structure. In some aspects, the techniques described herein relate to a semiconductor structure, wherein the first channel region includes a pull down transistor and the second channel region includes a pull up transistor. Having both pull up and pull down transistors enables fabrication of the semiconductor structure to include NFET and PFET channel layers, which increases density and efficiency of the semiconductor structure.

The present invention and an example fabrication process will now be described in detail with reference to the Figures.

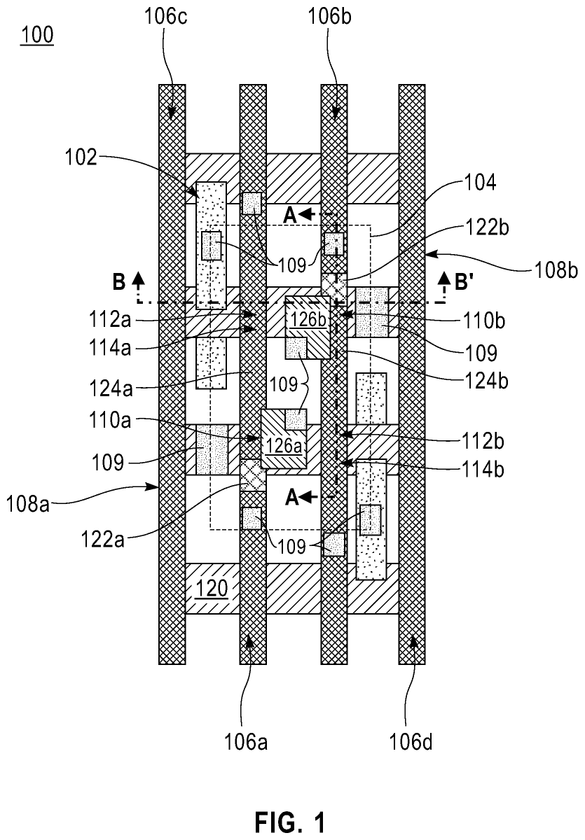

FIG. 1 depicts a schematic top see-through view of a semiconductor structure 100 having a vertical transistor static random-access memory (VT-SRAM or SRAM) cell 102 with a rectangular cell layout 104. Certain components of the SRAM cell 102 are visible through other components even though the components are located above or below the other components. The SRAM cell 102 is electrically connected between a first word line 106a and a second word line 106b, and between a first bit line 108a and a second bit line 108b. The illustrated embodiment shows additional word lines 106c, d, but the additional word lines 106c, d are used in different/other SRAM cells beside the instant SRAM cell 102. The word lines 106a, b and the bit lines 108a, b may include contacts 109 formed of electrically conductive materials such as copper, tungsten, cobalt, ruthenium, aluminum, other metals, or conductive non-metals. The word lines 106a, b and bit lines 108a, b are insulated from other components by dielectric 120. The dielectric 120 may include a non-crystalline solid material such as SiN, SiC, SiCN(H), or other silicon compounds for insulating, silicon dioxide (SiO₂) undoped silicate glass (USG), tetraethyl orthosilicate (TEOS), low-κ dielectric, or ultra low-κ dielectric materials, fluorosilicate glass (FSG), borophosphosilicate glass (BPSG), a spin-on low-κ dielectric layer, a chemical vapor deposition (CVD) low-κ dielectric layer or any combination thereof.

Electrically connected between the word lines 106a, b and the bit lines 108a, b, the SRAM cell 102 includes six transistors: a first pass gate transistor 110a, a first pull-up transistor 112a, and a first pull-down transistor 114a oriented along a first line (i.e., line A-A′); and a second pass gate transistor 110b, a second pull-up transistor 112b, and a second pull-down transistor 114b oriented along a second line (not illustrated, but similar in location to the illustrated second word line 106b). Thus, the SRAM cell 102 is organized as matching halves with half of the transistors on one half along the first line, and another half along the second line. Additionally, the pull-up transistors 112a, b are stacked vertically above the pull-down transistors 114a, b; a relationship that is visible in the cross-sectional views below.

The first pull-up transistor 112a and the first pull-down transistor 114a act as a first inverter, and are activated by a common inverter gate (as explained in more detail below) that surrounds the channel regions of the first pull-up transistor 112a and the first pull-down transistor 114a. The first inverter (i.e., the first pull-up transistor 112a and the first pull-down transistor 114a) is insulated from the first pass gate transistor 110a by a first separating insulator 122a. The second pull-up transistor 112b and the second pull-down transistor 114b are also activated by a common gate, and act as a second inverter. The second inverter (i.e., the second pull-up transistor 112b and the second pull-down transistor 114b) is insulated from the second pass gate transistor 110b by a second separating insulator 122b. The first inverter and the second inverter both include a gate extension (first gate extension 124a and second gate extension 124b) extending horizontally in a location vertically above the pass gate and the separating insulator. The first gate extension 124a connects the first inverter gate to a first cross couple 126a without requiring patterning or etching above the level of the inverter. The second gate extension 124b connects the first inverter gate to a second cross couple 126b without requiring patterning or etching above the level of the inverter. This functionality enables connection to the first cross couple 126a and the second cross couple 126b, respectively, without the potential for misalignment and reduced likelihood for defects caused by shorting to the bitline contact 109. The fabrication process and benefits of the gate extensions 124a, b are described in further detail below.

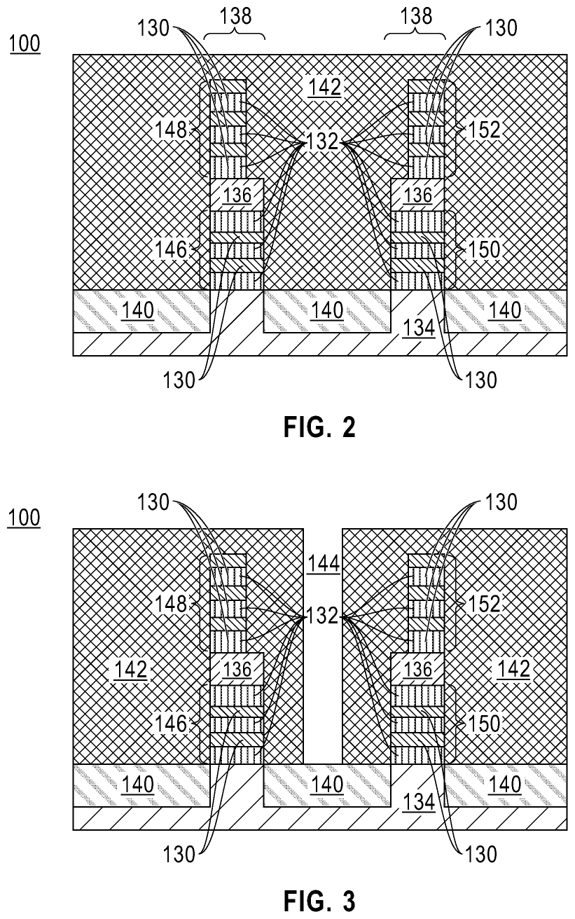

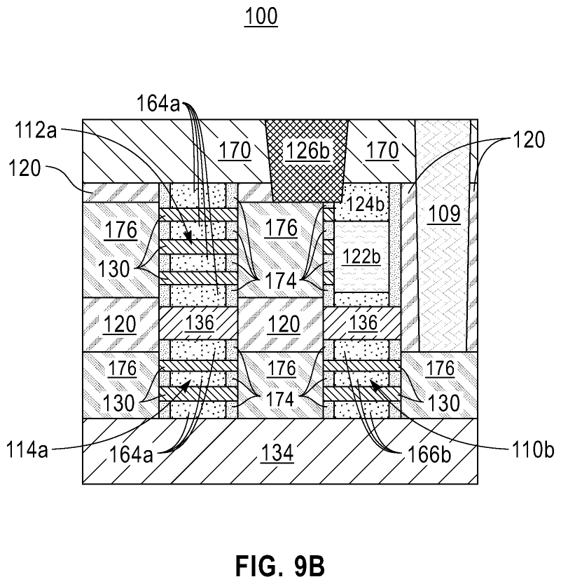

FIG. 2 depicts a cross-sectional side view of the semiconductor structure 100 of FIG. 1 along line A-A′ at one stage of fabrication, in accordance with one embodiment of the present invention. The semiconductor structure 100 is fabricated with stacks of nanosheets 130 and dummy layers 132. The nanosheets 130 and dummy layers 132 may be formed as blanket layers on a substrate 134. Additionally, as illustrated the nanosheets 130 and dummy layers 132 may be separated into a high channel region stacked above a low channel region by a stack dielectric 136. The stack dielectric 136 enables the pull-up transistors 112a, b to operate without affecting the pull-down transistors 114a, b (as shown below in FIGS. 9A and 9B).

The blanket layers of nanosheets 130 and dummy layers 132 may then be etched into channel pillars 138 using known techniques. Specifically, a directional etching process may be used to define the channel pillars 138, and the process may extend into the substrate 134 so that a shallow trench isolation (STI) 140 may be added to increase insulating between the channel pillars 138. The space between the channel pillars 138 is filled with a sacrificial dielectric 142 (e.g., amorphous silicon). In certain embodiments, the nanosheets 130 and dummy layers 132 may first be etched into fins corresponding to the word lines 106a-d illustrated in FIG. 1. These fins (i.e., word lines) may be lined with gate spacers (visible in FIG. 9B) by recessing the dummy layers 132 after formation of the fins.

FIG. 3 depicts a cross-sectional side view of the semiconductor structure 100 of FIG. 1 along line A-A′ at one stage of fabrication, in accordance with one embodiment of the present invention. The illustrated embodiment shows a first vertical etch gap 144 etched using a directional etch technique. For example, a hard mask (not illustrated) may be formed and patterned on the top of the semiconductor structure 100 and then a reactive ion etch (RIE) may be used to remove only the sacrificial dielectric 142 in a location between the channel pillars 138. The first vertical etch gap 144 may be etched to remove the sacrificial dielectric 142 completely to the STI 140. The etching process may be selective to the sacrificial dielectric 142 such that the gate spacer (again, visible in FIG. 9B) is not affected and remains lining the first vertical etch gap 144 on the lateral sides that are not illustrated in FIG. 3 (i.e., the lateral side that is deeper into the page and the lateral side that is out of the page of FIG. 3).

The first vertical etch gap 144 separates the channel pillars 138 and more clearly defines channel regions for the first pull-up transistor 112a, the first pull-down transistor 114a, the first pass gate transistor 110a, and a sacrificial region. That is a first channel region 146 is established for the second pull-down transistor 114b, a second channel region 148 is established for the second pull-up transistor 112b above the first channel region, a pass gate region 150 is established for the second pass gate transistor 110b, and a sacrificial region 152 is established above the pass gate region 150.

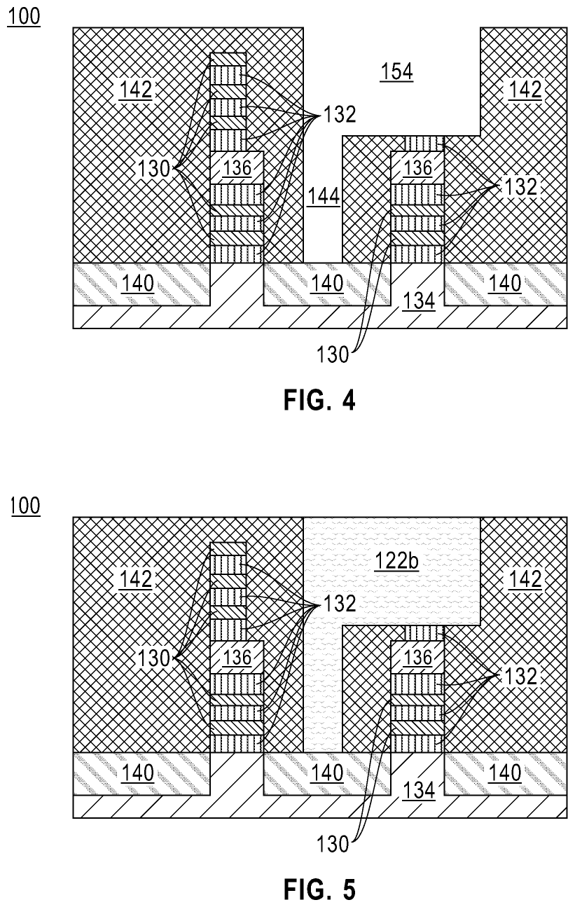

FIG. 4 depicts a cross-sectional side view of the semiconductor structure 100 of FIG. 1 along line A-A′ at one stage of fabrication, in accordance with one embodiment of the present invention. The semiconductor structure 100 is formed with a first horizontal etch gap 154 that expands the empty space of the first vertical etch gap 144 shown in FIG. 3. The first horizontal etch gap 146 expands along the first line with the second word line 106b, and extends laterally (i.e., into and out of the page) only to the extent of the fins of the channel region. The etch process does remove the sacrificial region 152, in addition to portions of the sacrificial dielectric 142. The etching of the first horizontal etch gap 154 does not affect the remaining channel regions (i.e., the pass gate region 150, the second channel region 148, and the first channel region 146).

FIG. 5 depicts a cross-sectional side view of the semiconductor structure 100 of FIG. 1 along line A-A′ at one stage of fabrication, in accordance with one embodiment of the present invention. The semiconductor structure 100 at this stage of fabrication includes the second separating insulator 122b formed by filling in the first vertical etch gap 144 and the first horizontal etch gap 154 with a dielectric material that has insulating properties. The second separating insulator 122b may include an oxide, for example, that is etch selective from the amorphous-silicon of the sacrificial dielectric 142, the nanosheets 130, the dummy layers 132, and other components of the semiconductor structure 100. The semiconductor structure 100 may be smoothed after the first vertical etch gap 144 and the first horizontal etch gap 154 are filled in. The smoothing may be done, for example, using chemical-mechanical polishing (CMP).

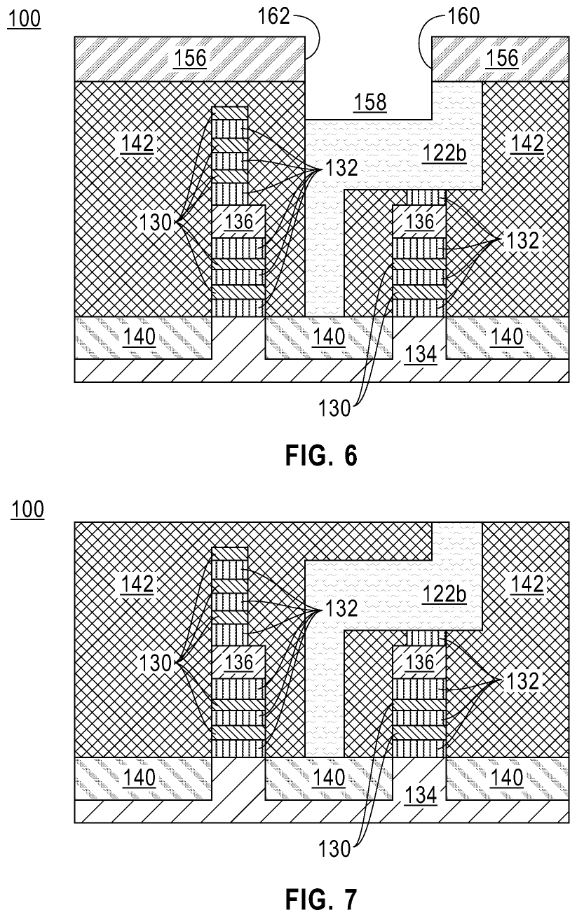

FIG. 6 depicts a cross-sectional side view of the semiconductor structure 100 of FIG. 1 along line A-A′ at one stage of fabrication, in accordance with one embodiment of the present invention. The semiconductor structure 100 at this stage includes an organic planarization layer (OPL) 156 that masks the semiconductor structure 100 in a pattern. The semiconductor structure 100 is then subjected to an etch process that is selective to remove the material of the second separating insulator 122b to form a gate extension gap 158. On a first side 160 of the OPL opening, the OPL 156 overlaps the second separating insulator 122b, and the second separating insulator 122b is etched on the border of the OPL 156. On a second side 162, however, the OPL 156 does not overlap the second separating insulator 122b. Since the etch process does not affect the sacrificial dielectric 142, the gate extension gap 158 is self-aligned to the sacrificial dielectric 142, meaning that the boundaries of the gate extension gap 158 are established (at least partially) independently of the lithographic patterning of the OPL 156. While not illustrated in FIG. 6, the gate extension gap 158 is also self-aligned to the gate spacer in the lateral directions (i.e., into and out of the page).

FIG. 7 depicts a cross-sectional side view of the semiconductor structure 100 of FIG. 1 along line A-A′ at one stage of fabrication, in accordance with one embodiment of the present invention. The semiconductor structure 100 at this stage has the gate extension gap 158 filled in with additional material from the sacrificial dielectric 142. The semiconductor structure 100 may also be treated with another round of CMP.

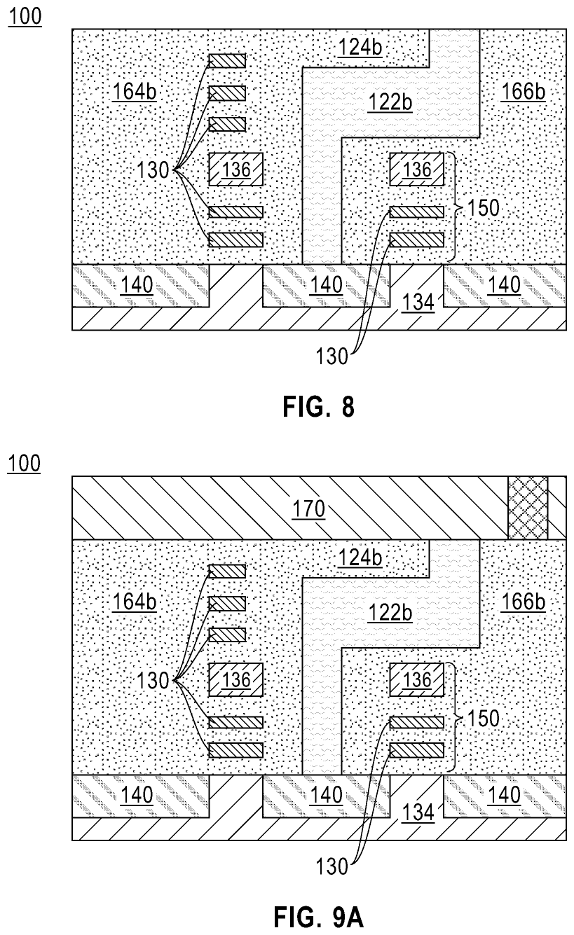

FIG. 8 depicts a cross-sectional side view of the semiconductor structure 100 of FIG. 1 along line A-A′ at one stage of fabrication, in accordance with one embodiment of the present invention. The semiconductor structure 100 at this stage includes a second inverter gate 164b and a second pass gate 166b that are made of a high-K metal gate material. The second inverter gate 164b replaces the sacrificial dielectric 142 and the dummy layers 132 on the left side of the second separating insulator 122b while the second pass gate 166b replaces the sacrificial dielectric 142 and the dummy layers 132 on the right side of the second separating insulator 122b. The sacrificial dielectric 142 and the dummy layers 132 may be selectively etched in one or more etch processes that do not affect the nanosheets 130 or the gate spacers.

The second inverter gate 164b activates the first channel region 146 and the second channel region 148 based on a charge to the second inverter gate 164b. The second inverter gate 164b includes the second gate extension 124b that extends horizontally in a location vertically above the pass gate region 150 and the second separating insulator 122b. The second gate extension 124b extends an electrical connectivity of the second inverter gate 164b in line with a second line without shorting to the second pass gate 166b.

FIG. 9A depicts a cross-sectional side view of the semiconductor structure 100 of FIG. 1 along line A-A′, at one stage of fabrication, in accordance with one embodiment of the present invention. The semiconductor structure 100 at this stage of fabrication includes a middle-of-line (MOL) 170 formed above the SRAM cell 102. FIG. 9A shows the MOL 170 includes the dielectric 120 over the SRAM cell 102 and one of the contacts 109 for activating the second pass gate 166b and the second pass gate transistor 110b.

FIG. 9B depicts a cross-sectional side view of the semiconductor structure 100 of FIG. 1 along line B-B′, at one stage of fabrication, in accordance with one embodiment of the present invention. FIG. 9B also shows the MOL 170, with the second cross couple 126b and one of the contacts 109 connected to the second bit line 108b and the second pass gate transistor 110b. FIG. 9B also shows a gate spacer 174 that contains the second pass gate 166b, the second separating insulator 122b, and the second gate extension 124b. The gate spacer 174 thus provides a self-aligned insulation between the second gate extension 124b and the contact 109 for the second bit line 108b. The second gate extension 124b also enables contact with the first pull-up transistor 112a. Specifically, the first pull-up transistor 112a and the first pull-down transistor 114a include source/drains (S/Ds) 176 that are epitaxially grown between the word lines 106a, b, c, d. The second cross couple 126b connects the second gate extension 124b with one of the S/Ds 176, so that the first inverter (i.e., the first pull-up transistor 112a and the first pull-down transistor 114a) and the second inverter (i.e., the second pull-up transistor 112b and the second pull-down transistor 114b) are electrically connected.

The methods described above are used in the fabrication of integrated circuit chips. The resulting integrated circuit chips can be distributed by the fabricator in raw wafer form (e.g., as a single wafer that has multiple unpackaged chips), as a bare die, or in a packaged form. In the latter case, the chip is mounted in a single chip package (e.g., a plastic carrier, with leads that are affixed to a motherboard or other higher level carrier) or in a multichip package (e.g., a ceramic carrier that has either or both surface interconnections or buried interconnections). In any case, the chip may be integrated with other chips, discrete circuit elements, and/or other signal processing devices as part of either an intermediate product or an end product.

The descriptions of the various embodiments of the present invention have been presented for purposes of illustration, but are not intended to be exhaustive or limited to the embodiments disclosed. Many modifications and variations will be apparent to those of ordinary skill in the art without departing from the scope and spirit of the described embodiments. The terminology used herein was chosen to best explain the principles of the embodiments, the practical application or technical improvement over technologies found in the marketplace, or to enable others of ordinary skill in the art to understand the embodiments disclosed herein.

What is claimed is:

1. A semiconductor structure, comprising:
a first pass gate oriented along a first line;
a first inverter in line with the first line, comprising:
a first channel region;
a second channel region stacked above the first channel region; and
an inverter gate around the first channel region and the second channel region, comprising a gate extension above the pass gate.

2. The semiconductor structure of claim 1, further comprising:
a second inverter; and
a cross couple electrically connected between the gate extension and a source/drain (S/D) of the second inverter.

3. The semiconductor structure of claim 2, wherein the second inverter is oriented along a second line different from the first line.

4. The semiconductor structure of claim 1, wherein the first channel region comprises nanosheet layers.

5. The semiconductor structure of claim 1, wherein the inverter gate is confined laterally by a gate spacer.

6. The semiconductor structure of claim 1, further comprising a separating insulator separating the inverter gate from the pass gate.

7. The semiconductor structure of claim 6, wherein the separating insulator comprises a first vertical section, a first horizontal section, and a second vertical section.

8. A method, comprising:
forming a separating insulator oriented along a first line between channel regions for a first pass gate and a first inverter;
etching a gate extension gap into the separating insulator above the pass gate; and
forming an inverter gate, wherein the inverter gate fills the gate extension gap with a high-metal gate material to form a gate extension.

9. The method of claim 8, further comprising forming a vertical etch gap in a sacrificial dielectric between the channel regions for the first pass gate and the first inverter.

10. The method of claim 9, further comprising forming a horizontal etch gap above the first pass gate, wherein etching the horizontal etch gap comprises etching a nanosheet.

11. The method of claim 8, further comprising forming a cross-couple between the gate extension and source/drain of a second inverter.

12. The method of claim 11, wherein the second inverter is oriented along a second line different from the first line.

13. The method of claim 8, wherein the gate extension gap is self-aligned between a gate spacer.

14. A semiconductor structure, comprising:
an inverter gate configured to activate an inverter gate transistor;
a pass gate; and
a separating insulator between the inverter gate and the pass gate, wherein the inverter gate comprises a gate extension extending horizontally along a first line in a location vertically above the pass gate and the separating insulator.

15. The semiconductor structure of claim 14, further comprising:
a second inverter; and
a cross couple electrically connected between the gate extension and a source/drain (S/D) of the second inverter.

16. The semiconductor structure of claim 15, wherein the second inverter is oriented along a second line different from the first line.

17. The semiconductor structure of claim 14, wherein the inverter gate is confined laterally by a gate spacer.

18. The semiconductor structure of claim 14, wherein the separating insulator comprises a first vertical section, a first horizontal section, and a second vertical section.

19. The semiconductor structure of claim 14, wherein the inverter gate transistor comprises a first channel region and a second channel region stacked above the first channel region.

20. The semiconductor structure of claim 19, wherein the first channel region comprises a pull down transistor and the second channel region comprises a pull up transistor.
